(19) United States
(12) Patent Application Publication
(10) Pub. No.: US 2003/0155930 A1
(43) Pub. Date: Aug. 21, 2003

(54) Current measuring circuit suited for batteries

(76) Inventor: Jes Thomsen, Copenhagen (DK)

Correspondence Address: NIXON & VANDERHYE, PC, 1100 N GLEBE ROAD, 8TH FLOOR, ARLINGTON, VA, 22201-4714, US

(21) Appl. No.: 10/258,441

(22) PCT Filed: Apr. 25, 2001
(86) PCT No.: PCT/SE01/00881

(30) Foreign Application Priority Data
Apr. 25, 2000 (SE) 0001475-3

(51) Int. Cl. G01R 31/08

(52) U.S. Cl. 324/522

(57) ABSTRACT

A measuring circuit (1) for e.g evaluating the current passing through a battery produces analog signals representing the potensials at two input terminals (9, 11) which are connected at each side of a shunt resistor (13). The circuit has a high-range stage (23) and a low-range stage (29), the two input terminals being alternatively connected to an input of the high-range stage. The output of the high-range stage is connected to an input of the low-range stage and the output terminals (5, 7) of the stages are output lines of the circuit. The stages comprise amplifiers (X2_{—}1, X2_{—}2) and hig-pass filters (25, 31) connected in front of the amplifiers. A line (21) for clock pulses is connected to a switching circuit (19) for the alternating connection of the input terminals. The switching circuit can comprise three electronic on-off switches (X1_{—}1, X1_{—}2, X1_{—}3). The amplifiers can be differential amplifiers, the positive and negative inputs of which are biassed to a voltage having a value being half the value of a supply voltage. This will allow negative potentials or input signals to be representad by positive output signals lower than the bias value and positive input signals to be represented by positive output signals larger than the bias value.

### TECHNICAL FIELD

The present invention relates to a measuring circuit particularly suited to measure and sample data of the condition of a battery or more particularly to measure an electrical quantity such as an electrical current which can vary from having a small intensity to a very large intensity and which can vary in sign.

### BACKGROUND OF THE INVENTION

In applications of electrochemical batteries in e.g. vehicles they are often provided with some kind of “intelligence”, such as a circuit for monitoring the charge/discharge state of the battery. Such a circuit requires measurements of the electric current flowing through the battery. Then a small shunt resistor is connected in a connection line of one of the battery terminal posts to a driven device/ground. However, the intensity of the electrical current passing through a starter battery has a very wide range and cannot easily be measured by means of standard measuring circuits. Such a current will also have different directions when the battery is charged and when it is used for powering some device.

Also in other applications there may exist a need for a measuring circuit which can measure some electrical quantity over a wide range. The electrical quantity can in most cases be easily converted to an electrical current by arranging some simple circuit.

A circuit for providing measurement signals of a large range is disclosed in the published European patent application No. 0 738 894. A potential to be measured is provided to a first amplifier providing a first output signal. In the case where the potential is too high, the first amplifier is saturated and a second output signal is provided from a second amplifier connected in parallel with the first amplifier. Small signals will thus only be amplified by one amplifier, the gain of which defining the resolution of the circuit. In U.S. Pat. No. 5,920,189 a circuit for measuring currents is disclosed comprising two parallel channels of high and low gain. A switch is provided for selecting one of the channels.

### SUMMARY OF THE INVENTION

It is an object of the invention to provide a non-costly measuring circuit which allows measuring an electrical quantity over a wide range, such as an electrical current over a wide range of the current intensity.

It is another object of the invention to provide a simple switching circuit for a measuring circuit.

Thus generally, a measuring circuit produces e.g. analog signals representing the potentials at one or two input terminals, each input terminal e.g. connected to a different one of the two sides or electrodes of a resistor, typically a shunt resistor having a low resistance or even very low resistance to provide measurements of the voltage over the resistor and thereby measurements of the electrical current through the resistor.

The circuit has at least two stages, a first and a second stage, e.g. a high-range stage and a low-range stage, the two input terminals being alternatingly connected to an input of the first stage which preferably is the high-range stage. The output of the first stage is connected to an input of the next, second stage and the output terminals of the two stages are connected as output lines of the circuit. The two stages each comprise amplifiers and preferably also high-pass filters connected in front of the amplifiers, to the inputs of the amplifiers. The gain in the stages can be substantially equal to each other. A very small signal is amplified in all stages, i.e. by at least two amplifiers connected in series with each other. This results in a very high resolution of the measuring circuit, the total range of the measuring circuit being set basically by the measuring range of the first stage.

Each stage can comprise a differential amplifier, the positive and negative inputs of which are biassed to a voltage having a value being half the value of a supply voltage. This will allow negative potentials or input signals to be represented by positive output signals lower than a center value and positive input signals to be represented by positive output signals larger than the center value.

A control input line of the measuring circuit can receive clock pulses and is connected to a switching circuit for performing the alternating connection of the input terminals. The switching circuit can comprise three identical, electronic on-off switches. Then a first switch is connected to a first one of the input terminals, the second switch to a second one of the input terminals and the third switch is connected to act as an inverter to make the first switch be on when the second switch is off and vice versa. The switching circuit has a simple structure, only requiring one additional switch for producing an alternating switching sequence.

Additional objects and advantages of the invention will be set forth in the description which follows, and in part will be obvious from the description, or may be learned by practice of the invention. The objects and advantages of the invention may be realized and obtained by means of the methods, processes, instrumentalities and combinations particularly pointed out in the appended claims.

### BRIEF DESCRIPTION OF THE DRAWINGS

While the novel features of the invention are set forth with particularly in the appended claims, a complete understanding of the invention, both as to organization and content, and of the above and other features thereof may be gained from and the invention will be better appreciated from a consideration of the following detailed description of non-limiting embodiments presented hereinbelow with reference to the accompanying drawings, in which:

FIG. 1 is a block diagram of a measuring setup,

FIG. 2 is a circuit diagram of a measuring circuit, and

FIGS. 3a, 3b and 3c are waveform diagrams showing input and output signals.

### DETAILED DESCRIPTION

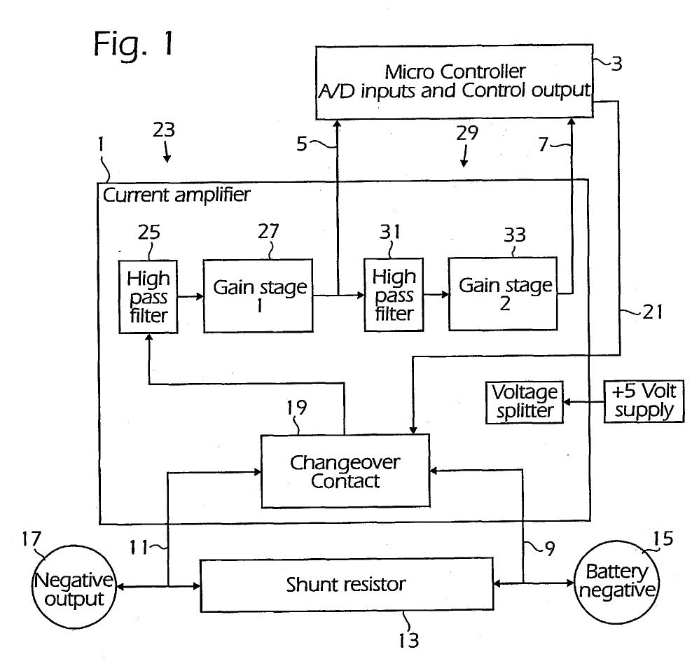

In FIG. 1 a block diagram of a measuring circuit 1 arranged for measuring the electrical current from a starter battery for an automotive vehicle is shown. The circuit 1 is built from relatively inexpensive components and introduces only a small increase of the series resistance of the electrical conductor, in which the current passes. The measuring circuit 1 is an analog circuit and is in the example of FIG. 1 adapted to measure the starter battery currents in two ranges of ±100 A and ±1 A. The operation of the measuring circuit is controlled by a micro-controller 3 having A/D-converting inputs. The measuring circuit 1 performs the sampling of an analog value and the amplification thereof to provide input signals of a suitable range to be received by the microcontroller 3 and converted to digital signals. The measuring circuit 1 has two output terminals or output lines 5, 7, one for providing an analog value representing the quantity to measured in a first range and another one for providing an analog value representing the same quantity to be measured but in a second, different range.

The measuring circuit 1 has two input terminals or input lines 9, 11 which in the example shown are connected to opposite sides or opposite ends of a shunt resistor 13 having a very low electrical resistance and connected between the negative terminal 15 of the starter battery, not shown, and the negative terminal 17 of devices, not shown, which are powered by the battery. Normally, when no measurement is being made, the two inputs are both connected to the negative terminal 15 of the battery, which conventionally is connected to or constitutes the common ground in automotive vehicles. The first output 5 for the range of ±100 A is then at a potential of approximatively 2.5 V. When a measurement of the electrical current in the line between the negative terminal 17 of the powered devices and the negative terminal post 15 of the battery is to be made, the output voltage at line 5 for the desired current range and for both input lines 9, 11 connected to ground is first digitized by the microcontroller 3 to obtain a reference value V_{ref} and then the second input line 11 of the measuring circuit is switched, by a changeover contact block 19 in the measuring circuit as controlled by a control line 21 from the microcontroller, to receive the mV signal from the shunt resistor 13. After a short delay, allowing the output voltage at the output line 5 to stabilize, a second A/D-conversion is made in the microcontroller to produce a measured value Vₘₑₐₛ and the desired, resulting value representing the current through the shunt resistor is calculated as Vₘₑₐₛ−V_{ref} and then corrected by a scaling factor and for the temperature of the shunt resistor to produce a value accurately representing the current through the shunt resistor 13.

The changeover contact block 19 performs the sampling as controlled by the microcontroller 3. It has a single output line which is connected to the input terminal of the components of the first, high-range block 23. This block comprises a highpass filter 25 providing a filtered output signal which is amplified by a first amplifier stage 27. The output of this amplifier stage is the output signal of the high-range block and is thus connected to the output terminal 5 of the measuring circuit. The output of the first amplifier stage 27 is connected to the input of the second, low-range block 29. This block comprises a high-pass filter 31 receiving the signal input to the block, the output filtered signal of the filter being provided to a second amplifier stage 33. The amplified signal output from the second amplifier stage is the output signal of the low-range block and is thus output from the measuring circuit at the output terminal 7.

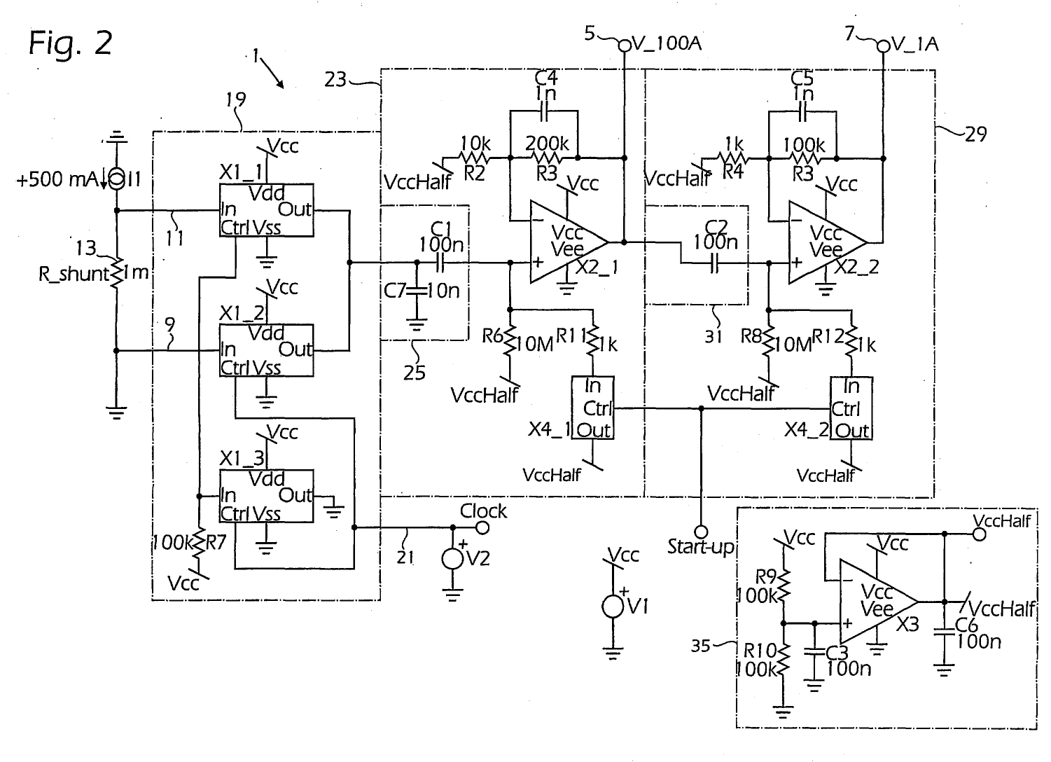

A circuit diagram of the measuring circuit 1 is shown in FIG. 2. The circuit obtains the electric power for its operation from an external supply, not shown, providing a supply voltage V_{cc}=5 V. This voltage is in a voltage divider circuit 35 provided to an end of a first resistor R9, the other end of this resistor being connected to an end of a second resistor R10, which has its other end connected to ground. The resistances of the first and second resistors are identical, the supply voltage thus being divided to provide half the supply voltage at the connection node between the two resistors. This voltage is provided to the positive input of an operational amplifier X3, the negative input and the output of which are interconnected, to provide at the output of the amplifier a voltage V_{ccHalf}=V_{cc}/2 =2.5 V, the output having a good driving capacity.

The output line 21 of the microcontroller 3 is normally high, i.e. at about 5 V, but gives for the measurement of the current in the shunt resistor negative pulses having e.g. a length of 5 ms, the pulses occurring e.g each 250 ms. These pulses are provided to the changeover contact block 19, which comprises three electronic switches X1_{—}1, X1_{—}2, X1_{—}3, these switches for instance being analog switches and each having an input terminal, an output terminal and a control input terminal. The input of the first electronic switch X1_{—}1 is connected to the input line 11 of the measuring circuit 1 and thus in the example shown to be connected to the positive end of the shunt resistor 13. The input of the second electronic switch X1_{—}2 is similarly connected to the input line 9 of the measuring circuit 1 and thus to the grounded, negative end of the shunt resistor 13. The output terminals of the first and second switches X1_{—}1, X1_{—}2 are connected to each other and to the input of the first range block 23, i.e. to the input of the high-pass filter 25.

The input terminal of the third switch X1_{—}3 and the control terminal of the first switch X1_{—}1 are both connected to the supply voltage Vcc through a resistor R7 having a relatively large resistance. The output terminal of the third switch X1_{—}3 is connected to ground. The control terminals of the second and third switches X1_{—}2, X1_{—}3 are both connected to the control line 21, receiving the clock pulses from the microcontroller. When the input control or clock signal on line 21 is high, the third switch X1_{—}3 is set to be closed or to a conducting state. This gives a low potential on its input terminal and thereby also the potential on the control terminal of the first switch X1_{—}1 will be low, this switch then being set to an open or non-conducting state. Thus for a high level of the clock signal the first switch X1_{—}1 will be open and the second switch X1_{—}2 will be closed. For a low level of the input signal on the control line 21 the third switch X1_{—}3 will be in an open state and the control input of the first switch X1_{—}1 will have a high level, making the first switch adopting a closed state. The interconnection of the third and first switches X1_{—}3, X1_{—}1 in this way performs an inversion of the input control signal from the clock line 19 when it reaches the first switch X1_{—}1.

When the level of the control signal on line 21 is high, the potential on the negative side of the shunt resistor 13, the ground potential, is provided to the input of the first, high-range block 23. When the level of the control signal on line 21 goes low, the potential on the positive side of the shunt resistor 13 is provided to the input of the high-range block 23. The signal input to this block is received by the high-pass filter 25 comprising a series capacitor C1. Also the input of the filter is connected to ground through a capacitor C7. The filtered signal is input to the first amplifier stage 27 and is received by the positive terminal of an operational or differential amplifier X2_{—}1, this positive terminal also being connected to V_{ccHalf}, i.e. half the supply voltage, through a resistor R6 having a relatively large resistance. The negative input of the amplifier X2_{—}1 is also connected to ground but through a resistor R2 having a smaller resistance. The negative input and the output of the amplifier X2_{—}1 are connected to each other through a parallel combination of a resistor R3 and a capacitor C4. The output terminal of the amplifier X2_{—}1 of the first stage is also connected to the high-range output terminal or line 5 of the measuring circuit 1 and to the input of the high-pass filter 31 of the low-range block 29.

The low-range measuring block 29 is built basically as the high-range block 23. The high-pass filter 31 thereof thus comprises a capacitor C2. The second amplifier stage 33 comprises an operational or differential amplifier X2_{—}2 having its positive input connected to the coupling and filtering capacitor C2 and to half the supply voltage V_{ccHalf} through a resistor R8 having a relatively large resistance. The negative input of the amplifier X2_{—}2 is connected to the same half supply voltage through a resistor R4 and is connected to the amplifier output terminal through a resistor R5 and a capacitor C5 connected in parallel. The output terminal of the second amplifier X2_{—}2 is also connected to the output terminal or output line 7 of the measuring circuit.

When there is a change of the potential on the input electrode of one of the coupling or filtering capacitors C1, C2 the respective capacitor will change its charge by being charged or discharged through the large resistor R6 or R8. The resulting change of the voltage between the inputs of the respective amplifier is amplified by the amplifier, the gain being defined by the relative magnitudes of the resistor in the feedback loop connected to the negative input and the resistor connecting the same terminal to ground, the gain in the first stage being equal to (1+R3/R2) which with the data of FIG. 2 gives a gain of 21, and the gain in the second stage being equal to (1+R5/R4) e.g. equal to 101.

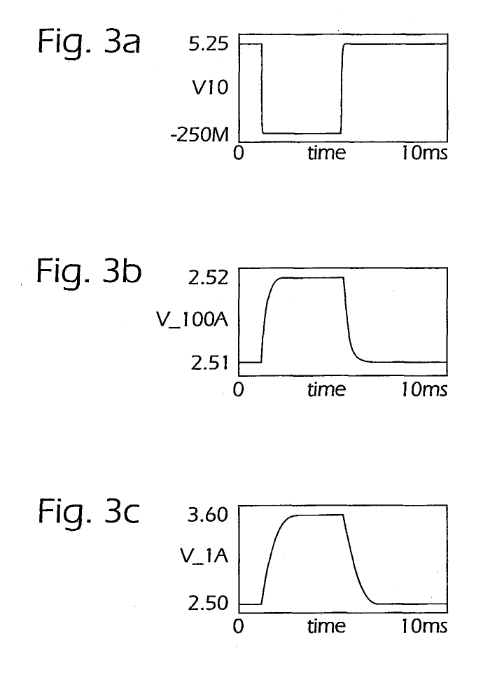

The waveforms of the input control signal on line 21 and the output signals on the output lines 5 and 7 are shown in the diagrams of FIGS. 3a, 3b and 3c. By the method of biassing the amplifiers X2_{—}1, X2_{—}2 by half the supply voltage, the signals output from the measuring circuit will indicate whether the respective input signals have a positive or negative sign. Thus an input signal nominally equal to zero will give output signals of 2.5 V and a nominally negative input signal will give output signals smaller than 2.5 V, etc. The values actually representing the current through the shunt resistor are obtained by a subtraction, after digitizing, in the microcontroller 3, as described above.

In the start-up stage of the circuit of FIG. 2, there can be a significant time period which has to elapse until the relatively large filtering and coupling capacitors C1, C2 at the inputs of the amplifiers X2_{—}1, X2_{—}2 have been charged from the voltage supply of V_{ccHalf}. These capacitors can then be more rapidly charged through small resistors R11, R12 connected in parallel with the large resistors R6, R8 respectively, switches X4_{—}1, X4_{—}2 being connected in series with the small resistors and controlled to be closed only in the start-up stage by a suitable signal on the control terminals of the switches and to be open otherwise.

The shunt resistor 13 can for example be made from a Cu-winding and then has a temperature coefficient of approximately 0.393%/° C. If the measurement is to made on a battery in a vehicle and if the measurement has to be very accurate, such as required when used as input data in an algorithm for estimating the remaining charge of the battery, the shunt resistor can have a very varying temperature, for instance if used in the northern countries. Thus, if the shunt resistor for example has a resistance value of 1 milliohm at 20° C. the resistance value will at −40° C. be 0.764 milliohm and at 70° 1.196 milliohm. Thus, in order to obtain a correct value a correction of the measured current must be made, e.g. in the microcontroller unit 3. Then, a temperature sensor, not shown, must be arranged at the shunt resistor 13 and connected provide a signal representing the sensed temperature to an A/D-input of the microcontroller.

While specific embodiments of the invention have been illustrated and described herein, it is realized that numerous additional advantages, modifications and changes will readily occur to those skilled in the art. Therefore, the invention in its broader aspects is not limited to the specific details, representative devices and illustrated examples shown and described herein. Accordingly, various modifications may be made without departing from the spirit or scope of the general inventive concept as defined by the appended claims and their equivalents. It is therefore to be understood that the appended claims are intended to cover all such modifications and changes as fall within a true spirit and scope of the invention.

1. A measuring circuit, having a first input measurement terminal and output measurement terminals, for producing on the output measurement terminals signals representing the potential at the first input measurement terminal, characterized by at least two stages having different measuring ranges, a first one of the at least two stages having a first measuring range and an input terminal and an output terminal and a second one of the at least two stages having a second measuring range and an input terminal and an output terminal, the first input measurement terminal connected to the input terminal of the first one of the at least two stages and the output terminal of the first one of the at least two stages connected to the input terminal of the second one of the at least two stages, the output terminals of the at least two stages connected to the output measurement terminals of the measuring circuit, the first and second ones of the at least two stages each comprising an amplifier for amplifying signals received on the input terminal of the respective stage to produce amplified signals on the output terminal of the respective stage.

2. A measuring circuit according to claim 1, characterized in that the first one of the at least two stages is a high-range stage and the second one of the at least two stages is a low-range stage.

3. A measuring circuit according to any of claims 1-2, characterized in that each of the at least two stages comprises a high-pass filter connected in an input line of the amplifier of the respective stage.

4. A measuring circuit according to any of claims 1-3, characterized in that each of the at least two stages comprises a differential amplifier, the two inputs of which are biassed to a bias voltage having a bias value equal to half the value of a supply voltage, allowing that negative input signals are represented by positive output signals lower than the bias value and positive input signals are represented by positive output signals larger than the bias value.

5. A measuring circuit according to any of claims 1-4, characterized by a second input measurement terminal and a switching circuit connected to the first and second input measurement terminals to periodically or alternatingly feed the potential at the first input measurement terminal and the second input measurement terminal to the input terminal of the first one of the at least two stages, thereby producing periodic signals representing alternatingly the potentials on the first and second measurement terminals.

6. A measuring circuit according to claim 5, characterized by a control input line adapted to receive clock pulses, the control input line being connected to the switching circuit and the switching circuit comprising two controlled electronic on-off switches.

7. A measuring circuit according to claim 5, characterized by a control input line adapted to receive clock pulses, the control input line being connected to the switching circuit and the switching circuit comprising electronic on-off switches, a first one of the electronic on-off switches connected to the first input measurement terminal, a second one of the electronic on-off switches connected to the second input measurement terminal and a third one of the electronic on-off switches connected to act as an inverter to make the first one of the electronic on-off switches be on when the second one of the electronic on-off switches is off and vice versa.

8. A measuring circuit according to any of claims 5-7, characterized in that the first and second input measurement terminals are connected to the ends of a resistor in order to measure a voltage drop over the resistor and thereby provide a value of an electrical current flowing through the resistor.

9. A switching circuit for a measuring circuit and adapted to receive clock pulses to provide an alternating switching of signals from first and second input measurement terminals to an input stage of the measuring circuit, characterized by electronic on-off switches, a first one of the electronic on-off switches connected to the first input measurement terminal, a second one of the electronic on-off switches connected to the second input measurement terminal and a third one of the electronic on-off switches connected to act as an inverter to make the first one of the switches be on when the second one of the switches is off and vice versa.

10. A switching circuit according to claim 9, characterized in that the second and third ones of the electronic on-off switches are adapted to receive the clock signals on control input terminals, the third one of the electronic on-off switches having input and output terminals, one thereof connected to electronic ground potential and another one thereof connected to a control input terminal of the first one of the electronic on-off switches.

11. A switching circuit according to claim 9, characterized in that said another one of the input and output terminals of the third one of the electronic on-off switches is also connected to a supply voltage through a resistor.
